(19) United States
(12) Patent Application Publication
(10) Pub. No.: US 2002/0118123 A1
(43) Pub. Date: Aug. 29, 2002

(54) Space keyboard system using force feedback and method of inputting information therefor

(76) Inventors: Sung-cheol Kim, Seoul (KR); Tae-sik Park, Seoul (KR)

Correspondence Address: STAAS & HALSEY LLP, 700 11TH STREET, NW, SUITE 500, WASHINGTON, DC, 20001, US

(21) Appl. No.: 09/987,686

(22) Filed: Nov. 15, 2001

(30) Foreign Application Priority Data
Feb. 27, 2001 (KR) 2001-10017

(51) Int. Cl. H03M 11/00; H03K 17/94

(52) U.S. Cl. 341/34; 345/173

(57) ABSTRACT

A space keyboard system, which informs a user whether or not a character is input using a force feedback method, and a method for inputting information therefor. The method of inputting information in a virtual space, comprising detecting a motion of a finger in space, interpreting the motion information detected and determining the location of the finger, and inputting a character information corresponding to the location of the finger that is determined and applying a force to the finger.

### CROSS-REFERENCE TO RELATED APPLICATION

This application claims the benefit of Korean Application No. 2001-10017, filed Feb. 27, 2001, in the Korean Industrial Property Office, the disclosure of which is incorporated herein by reference.

### BACKGROUND OF THE INVENTION

1. Field of the Invention

The present invention relates to an information input system, and more particularly, to a space keyboard system, which informs a user whether or not a character is input using a force feedback method, and a method of inputting information therefore.

2. Description of the Related Art

In the prior art, an information processing apparatus, such as a computer, uses a keyboard for inputting commands, characters, and numbers. A conventional information input apparatus using the keyboard, as shown in FIG. 1, includes a key unit 110 having keys, a control unit 120 for detecting a plurality of keys being pushed and decoding signals thereof, and a computer system 130 for displaying a character corresponding to the decoded signal.

This conventional keyboard is generally connected to a desktop computer and is not appropriate for a wearable or portable system. Therefore, to solve this problem, a keyboard that can be used in any space is currently under development. However, even when a keyboard is desired to be implemented in a virtual space, a user may not directly sense whether characters input through the motion of the user's fingers are correctly input. Also, the user may become fatigued or physically tired since the user inputs characters by viewing the screen of the computer.

### SUMMARY OF THE INVENTION

It is an object of the present invention to provide a space keyboard system, in which, when a character is input in response to the motion of a user's finger, force is applied to a predetermined part of the finger so that the user can confirm that a character is input, and a method for inputting information thereof.

Additional objects and advantages of the invention will be set forth in part in the description which follows and, in part, will be obvious from the description, or may be learned by practice of the invention.

To accomplish the object of the present invention, there is provided a space keyboard system comprising a sensor unit that is attached to a predetermined part of a finger which senses motion information of the finger, an information input processing unit which interprets modulated data of the motion information of the finger, displays a character corresponding to a location of the finger with respect to a virtual keyboard in space, determines the finger corresponding to the displayed character, and generates an input completion signal having an identifier of the determined finger, a processor unit which converts the finger motion information detected by the sensor unit into converted data, modulates the converted data, sends the modulated data to the information input processing unit, and receives the input completion signal of an input character from the information input processing unit, and a force generating unit that is attached to a predetermined part of the finger which applies force to the finger corresponding to the input completion signal if the input completion signal is received.

In another embodiment, the present invention provides a space keyboard system for inputting information in space, the space keyboard system comprising: a sensor unit that is attached to a predetermined part of a finger which senses motion information of the finger, a processor which determines a location of the finger with respect to a virtual keyboard in space on the basis of the finger motion information detected by the sensor unit, sends the location information to a computer and receives an input completion signal identifying the finger corresponding to the character input from the computer, and a force generating unit that is attached to a predetermined part of the finger which applies force to the finger corresponding to the input completion signal if the input completion signal is received.

To accomplish the above and other objects of the present invention, there is provided a method of inputting information in space, comprising providing a sensor unit generating an acceleration and/or angle signals to a first predetermined part of a finger, providing a force generating unit to a second predetermined part of the finger, detecting a motion of the finger with the sensor unit, interpreting the motion information detected and determining a location of the finger with respect to a virtual keyboard in space, and inputting a character corresponding to the location of the finger that is determined and applying the force to the finger with the force generating unit.

### BRIEF DESCRIPTION OF THE DRAWINGS

The above objects and advantages of the present invention will become more apparent by describing in detail preferred embodiments thereof with reference to the attached drawings in which:

FIG. 1 is a block diagram of an information input system for inputting information through a conventional keyboard;

FIG. 2 is a preferred embodiment of a space keyboard system according to the present invention;

FIG. 3 is a block diagram showing the space keyboard system according to the present invention; and

FIG. 4 is a flowchart of a method for inputting information in a virtual space according to the present invention.

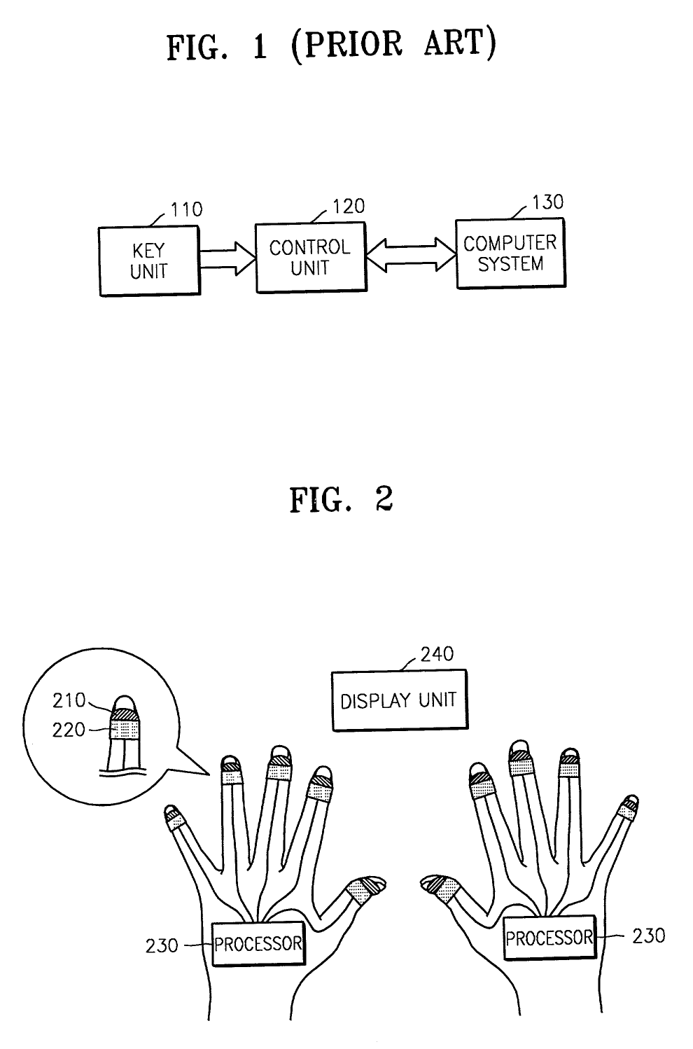

### DESCRIPTION OF THE PREFERRED EMBODIMENTS

Reference will now be made in detail to the present preferred embodiments of the present invention, examples of which are illustrated in the accompanying drawings, wherein like reference numerals refer to the like elements throughout. The embodiments are described below in order to explain the present invention by referring to the figures.

First, to implement the present invention, it is assumed that there is a virtual keyboard in space. That is, a manufacturer may set the virtual keyboard in space before the product is shipped, or a user may set the virtual keyboard in a desired location in space from the computer. Also, through a training process, the user can input information from a predetermined location in space.

FIG. 2 is an embodiment of a space keyboard system according to the present invention. Referring to FIG. 2, an information input apparatus is formed with sensors 220, force-generating units 210, and a processor 230 in each hand. The sensors 220 are attached to each finger of both hands, and sense the motion of the fingers. As an embodiment of the sensors 220, an acceleration sensor may be used. The force-generating units 210 are attached to each finger and correspond with the sensors 220 and generate force to a predetermined part of the fingers. A device capable of generating a force, vibration or a small electric shock is preferably used as the force-generating unit 210. The processor 230 is located on the back of a hand or on a wrist and communicates information with the sensors 220 and the force generating units 210. As shown in FIG. 2, the sensors 220 and the force generating units 210 are preferably located at the end of each finger. However, the sensors 220 and the force generating units 210 may be located at any part of the finger.

Motion information of the finger detected by the sensor 220, for example, acceleration information and/or angle information, are sent by wire or wirelessly to an information input processing apparatus, such as a computer, and converted into location information in the information input processing apparatus. Then, referring to the location information, the information input processing apparatus displays a character, which is selected by a user finger, on a display unit 240. At the same time, an input completion signal of the selected character is fed back by wire or wirelessly to the force-generating unit 210 attached to the corresponding finger. At this point, the user is able to confirm, through the force given to the corresponding finger, that the information is actually input.

The location information of a finger can be determined by processing acceleration information and/or angle velocity information using a sensor, such as a gyro sensor or an inertial micro-electro mechanical system (IMEMS) sensor, which transforms the acceleration and/or angle velocity information into an electrical signal. For example, all five of a user's fingers may have an IMEMS sensor which generates electrical signals in response to motion of the user's fingers and/or hand. If the user moves one of the fingers (i.e. up to down corresponding to a selection of a character) more than the other fingers, the electrical signal of that finger is the strongest. A processor can determine the location of the fingers corresponding to a particular motion using motion information generated by each of the sensors.

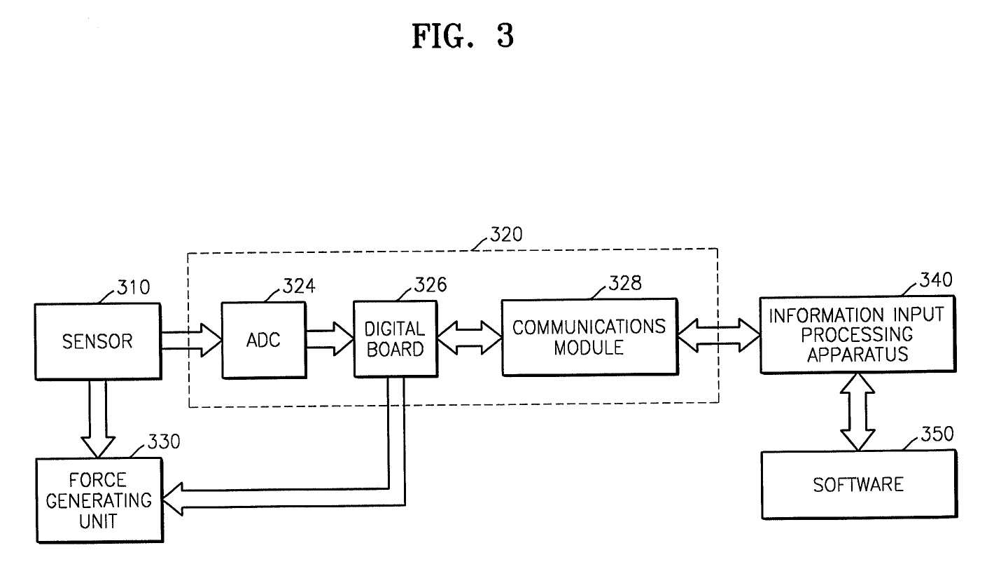

FIG. 3 is a block diagram showing the space keyboard system according to the present invention. Referring to FIG. 3, a sensor 310 outputs motion information of a finger as acceleration information and/or angle information in an analog or digital signal form. A processor 320 converts the finger motion information detected by the sensor 310 into data having a predetermined form, sends the data to an information input processing apparatus 340, and receives an input completion signal identifying the finger corresponding to a character which is input from the information input processing apparatus 340.

More specifically, an analog-to-digital converter (ADC) 324 in the processor 320 converts the motion information generated by the sensor 310 into a digital signal from an analog signal. A digital board 326 converts the motion information output from the ADC 324 into the converted data having the predetermined form, which can be used by the information input processing apparatus 340, and outputs the received input completion signal to the force-generating unit 330 of the corresponding finger. A communications module 328 modulates the converted data having the predetermined form from the digital board 326, and sends the modulated data to the information input processing apparatus 340 by wire or wirelessly. The communication module 328 also demodulates the input completion signal received from the information input processing apparatus 340.

The information input processing apparatus 340 interprets the modulated data (finger motion information) sent by the processor 320 and generates a character corresponding to the location of the finger with respect to a virtual keyboard in space. The information input processing apparatus 340 determines the finger corresponding to the generated character and outputs the input completion signal having an identifier (ID) of the finger, with which the character was input, for the force-generating unit 330 corresponding to the location of the identified finger.

The software 350 is a program for driving the information input processing apparatus 340, so that the space keyboard is managed.

In another embodiment of the present invention, the motion information detected by the sensor 310 may be directly output to the force-generating unit 330 so that the user can confirm the input of a character.

In still another embodiment of the present invention, the functions of the processor 320 and of the information input processing apparatus 340 may be set differently. That is, after interpreting the motion information detected by the sensor 310, the processor 320 determines the location of the finger with respect to a virtual keyboard in space, sends the location information to the information input processing apparatus 340, and receives an input completion signal from the information input processing apparatus 340. The information input processing apparatus 340 inputs a character on the basis of the received finger location information, generates the input completion signal having an identifier of the finger, and sends the input completion signal corresponding to the character input based on the location information of the finger to the processor 320.

In still another embodiment of the present invention, the processor 320 interprets finger motion information detected by the sensor 310 and may directly output the input completion signal to the force generating unit 330.

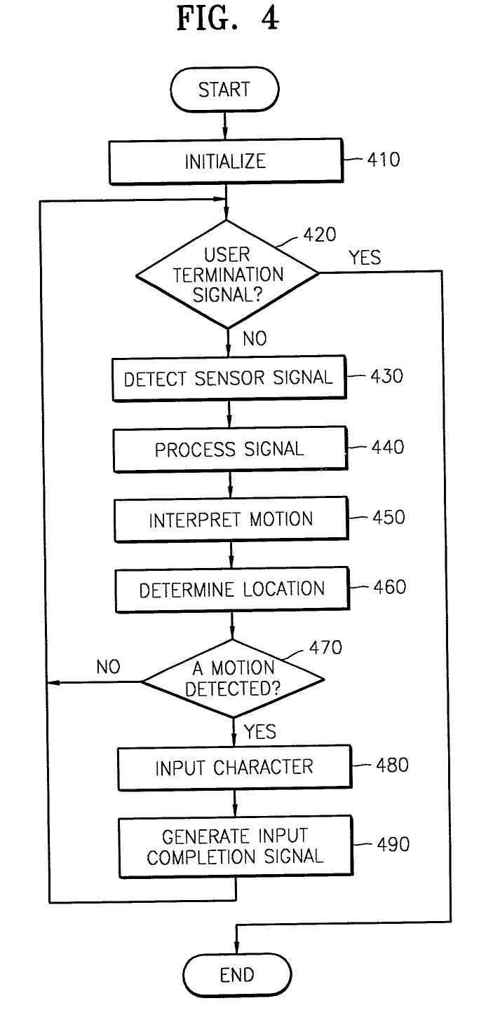

FIG. 4 is a flowchart of a method of inputting information in a virtual space according to the present invention. First, the sensor 310 and the processor 320 are initialized in step 410.

Then, a determination is made as to whether or not a user termination signal is detected in step 420. If the user termination signal is detected, information processing is finished. If the user termination signal is not detected, the sensor 310 in step 430 detects finger motion information. The detected finger motion information is converted into data having a predetermined form, which can be used by the information input processing apparatus 340 in step 440. After interpreting the converted motion information in step 450, the location of the finger with respect to a virtual keyboard in space is determined based on the interpreted information in step 460. Using the sensor 310 in step 470, it is determined whether the motion information corresponding to a character selected by the finger in a virtual space is detected. If the motion is detected, the character corresponding to the location of the finger with respect to the virtual keyboard in space is input in step 480.

In step 490, the character is displayed on a screen at the same time the input completion signal is output having an identifier of the finger corresponding to the input character. Steps 420 through 490 are repeated until the user termination signal is detected in step 420.

According to the present invention as described above, when a character is input by a finger motion in space, a force is given to the end of the finger so that the user can confirm the input without watching the screen.

Although a few preferred embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A method of inputting information in a virtual space, comprising:
detecting motion information of a finger in space;
interpreting the motion information detected and determining the location of the finger; and
inputting a character corresponding to the location of the finger that is determined and applying a force to the finger.

2. The method of claim 1, wherein the motion information is communicated by wire or wirelessly.

3. A virtual space keyboard system comprising:
a sensor unit that is attached to a first predetermined part of a finger which senses motion information of the finger;
an information input processing unit which interprets modulated data of the motion information of the finger, displays a character corresponding to a location of the finger with respect to the virtual space keyboard in space, determines the finger corresponding to the displayed character, and generates an input completion signal having an identifier of the determined finger;
a processor unit which converts the motion information detected by the sensor unit into converted data, modulates the converted data, sends the modulated data to the information input processing unit, and receives the input completion signal identifying the finger corresponding to the character input from the information input processing unit; and
a force generating unit that is attached to a second predetermined part of the finger, which applies a force to the finger corresponding to the input completion signal if the input completion signal is received.

4. The virtual space keyboard system of claim 3, wherein the processor unit comprises:
an analog-to-digital converting unit which converts the motion information detected by the sensing unit into a digital signal;
a digital board which converts the digital signal of the motion information into the converted data, and outputs the received input completion signal to the force generating unit; and
a communications module unit which modulates the converted data representing the motion information from the digital board unit, sends the modulated data to the information input processing unit, and receives the input completion signal from the information input processing unit.

5. The virtual space keyboard system of claim 3, wherein the force generating unit is a device generating vibration or a small electric shock.

6. The virtual space keyboard system of claim 3, wherein the sensor unit senses acceleration information of the finger and/or angle speed information of the finger.

7. The virtual space keyboard system of claim 3, wherein the processor unit is attached to a back of a hand or on a wrist.

8. The virtual space keyboard system of claim 3, wherein the sensor unit and the force generating unit are located at the end of the finger.

9. The virtual space keyboard system of claim 8, wherein the sensor unit and the force generating unit are adjacent to each other.

10. The virtual space keyboard system of claim 3, wherein the motion information, and/or the modulated data, and/or the input completion signal are/is communicated by wire or wirelessly.

11. The virtual space keyboard system of claim 3, wherein the information input processing unit is a computer.

12. A virtual space keyboard system comprising:
a sensor unit that is attached to a first predetermined part of a finger which senses motion information of the finger;
an information input processing unit which displays a character based on received location information of the finger with respect to the virtual space keyboard in space and generates an input completion signal;
a processor unit which determines the location information of the finger based on the motion information detected by the sensor unit, sends the location information to the information input processing unit, and receives the input completion signal corresponding to the character input from the information input processing unit; and
a force generating unit that is attached to a second predetermined part of the finger, which applies a force to the finger corresponding to the input completion signal if the input completion signal is received.

13. The virtual space keyboard system of claim 12, wherein the force generating unit is a device generating vibration or a small electric shock.

14. The virtual space keyboard system of claim 12, wherein the sensor unit senses acceleration information of the finger and/or angle speed information of the finger.

15. The virtual space keyboard system of claim 12, wherein the processor unit is attached to a back of a hand or on a wrist.

16. The virtual space keyboard system of claim 12, wherein the sensor unit and the force generating unit are located at the end of the finger.

17. The virtual space keyboard system of claim 16, wherein the sensor unit and the force generating unit are adjacent to each other.

18. The virtual space keyboard system of claim 12, wherein the motion information, and/or the location information, and/or the input completion signal are/is communicated by wire or wirelessly.

19. The virtual space keyboard system of claim 12, wherein the information input processing unit is a computer.

20. A virtual space keyboard system comprising:
a sensor unit that is attached to a first predetermined part of a finger which senses motion information of the finger;
an information input processing unit which displays a character based on received location information of the finger with respect to the virtual space keyboard in space;
a processor unit which determines the location information of the finger based on the motion information detected by the sensor unit, and sends the location information to the information input processing unit; and
a force generating unit that is attached to a second predetermined part of the finger, which applies a force to the finger in response to the motion information of the finger.

21. The virtual space keyboard system of claim 20, wherein the force generating unit is a device for generating vibration or a small electric shock.

22. The virtual space keyboard system of claim 20, wherein the sensor unit senses acceleration information of the finger and/or angle speed information of the finger.

23. The virtual space keyboard system of claim 20, wherein the processor unit is attached to a back of a hand or on a wrist.

24. The virtual space keyboard system of claim 20, wherein the sensor unit and the force generating unit are located at the end of each finger.

25. The virtual space keyboard system of claim 24, wherein the sensor unit and the force generating unit are adjacent to each other.

26. The virtual space keyboard system of claim 20, wherein the motion information and/or the location information are/is communicated by wire or wirelessly.

27. The virtual space keyboard system of claim 20, wherein the information input processing unit is a computer.

28. A virtual space keyboard system to input information to a computer, the virtual space keyboard system comprising:
a sensor unit that is attached to a first predetermined part of a finger which senses motion of the finger;
a processor unit which determines location information of the finger with respect to the virtual space keyboard in space based on the motion information detected by the sensor unit, sends the location information to the computer, and receives the input completion signal corresponding to the input information from the computer; and
a force generating unit that is attached to a second predetermined part of the finger, which applies a force to the finger corresponding to the input completion signal if the input completion signal is received.

29. A virtual space keyboard system to input information to a computer, the virtual space keyboard system comprising:
a sensor unit that is attached to a first predetermined part of a finger which senses motion information of the finger;
a processor unit which determines location information of the finger with respect to the virtual space keyboard in space based on the motion information detected by the sensor unit, and sends the location information to the computer; and
a force generating unit that is attached to a second predetermined part of the finger, which applies a force to the finger in response to the motion information of the finger.

30. An information input device attached to a finger and/or a hand to input motion information of the finger to a processor unit, the information input device comprising:
a sensor unit to contact a first predetermined part of the finger which detects motion information of the finger and sends the motion information to the processor unit; and
a force generating unit to contact a second predetermined part of the finger which receives an input completion signal corresponding to the input motion information of the finger and generates a force to the second predetermined part of the finger if the input completion signal is received.

31. The information input device of claim 30, further comprising a cover, wherein the sensor unit is attached to the cover to be placed on the finger and the force generating unit is attached to the cover to be placed on the finger.

32. The information input device of claim 31, wherein the cover comprises a glove covering the finger and a hand to which the finger is attached.

33. A method of inputting information in a virtual space, comprising:
detecting motion information of fingers in space;
interpreting the motion information detected and determining locations of the fingers; and
inputting characters corresponding to the locations of the fingers that are determined and applying a force to the fingers.

34. The method of claim 33, wherein the motion information is communicated by wire or wirelessly.

35. A virtual space keyboard system comprising:
sensor units that are attached to first predetermined parts of fingers which sense motion of the fingers, to output motion information;
an information input processing unit which interprets modulated data of the motion information of the fingers, displays characters corresponding to locations of the fingers with respect to the virtual space keyboard in space, determines the fingers corresponding to the displayed characters, and generates input completion signals having identifiers of the determined fingers;
a processor unit which converts the motion information detected by the sensor units into converted data, modulates the converted data, sends the modulated data to the information input processing unit, and receives the input completion signals identifying the fingers corresponding to characters input from the information input processing unit; and
force generating units that are attached to second predetermined parts of the fingers, wherein each force generating unit generates a force to a second predetermined part of a one of the fingers in response to a corresponding one of the input completion signals.

36. The virtual space keyboard system of claim 35, wherein the processor unit comprises:
an analog-to-digital converting unit which converts the motion information detected by the sensing units into digital signals;
a digital board which converts the digital signals of the motion information into the converted data, and outputs the received input completion signals to the force generating units of the fingers corresponding to the characters input; and
a communications module unit which modulates the converted data representing the motion information from the digital board unit, sends the modulated data to the information input processing unit, and receives the input completion signals from the information input processing unit.

37. A virtual space keyboard system comprising:
sensor units that are attached to first predetermined parts of fingers which sense motion of the fingers, to output motion information;
an information input processing unit which displays characters based on received location information of the fingers with respect to the virtual space keyboard in space and generates input completion signals;
a processor unit which determines the location information of the fingers based on the motion information detected by the sensor units, sends the location information to the information input processing unit, and receives the input completion signals corresponding to the characters input from the information input processing unit; and
force generating units that are attached to second predetermined parts of the fingers, wherein each force generating unit generates a force to a second predetermined part of a one of the fingers in response to a corresponding one of the input completion signals.

38. A virtual space keyboard system comprising:
sensor units that are attached to first predetermined parts of fingers which sense motion of the fingers, to output motion information;
an information input processing unit which displays characters based on received location information of the fingers with respect to the virtual space keyboard in space;
a processor unit which determines the location information of the fingers based on the motion information detected by the sensor units, and sends the location information to the information input processing unit; and
force generating units that are attached to second predetermined parts of the fingers, wherein each force generating unit generates a force to a second predetermined part of a one of the fingers in response to a corresponding one of the motion information.

39. A virtual space keyboard system to input information to a computer, the virtual space keyboard system comprising:
sensor units that are attached to first predetermined parts of fingers which sense motion of the fingers, to output motion information;
a processor unit which determines the location information of the fingers with respect to the virtual space keyboard in space based on the motion information detected by the sensor units, sends the location information to the computer, and receives the input completion signals corresponding to the input information from the computer; and
force generating units that are attached to second predetermined parts of the fingers, wherein each force generating unit generates a force to a second predetermined part of a one of the fingers in response to a corresponding one of the input completion signals.

40. A virtual space keyboard system to input information to a computer, the virtual space keyboard system comprising:
sensor units that are attached to first predetermined parts of fingers which sense motion information of the fingers, to output motion information;
a processor unit which determines location information of the fingers with respect to the virtual space keyboard in space based on the motion information detected by the sensor units, and sends the location information to the computer; and
force generating units that are attached to second predetermined parts of the fingers, wherein each force generating unit generates a force to a second predetermined part of a one of the fingers in response to a corresponding one of the motion information.

41. A processor unit to communicate motion information detected by sensor units attached to first predetermined parts of fingers to a computer and input completion signals generated by the computer to force generating units attached to second predetermined parts of the fingers, wherein the input completion signals correspond to characters input by the computer based on the motion information of the fingers, the processor unit comprising:
an analog-to-digital converting unit which converts the motion information detected by the sensing units into digital signals;
a digital board which converts the digital signals of the motion information into the converted data, and outputs the received input completion signals to the force generating units; and
a communications module unit which modulates the converted data representing the motion information from the digital board unit, sends the modulated data to the computer, and receives the input completion signals from the computer.

42. An information input device attached to fingers to input motion information of the fingers to a processor unit, the information input device comprising:
sensor units to contact first predetermined parts of the fingers which detect motion of the fingers and send motion information to the processor unit; and
force generating units to contact second predetermined parts of the fingers which receive input completion signals corresponding to the input motion information of the fingers, wherein each force generating unit generates a force to a second predetermined part of a one of the fingers in response to a corresponding one of the input completion signals.

43. The information input device of claim 40, further comprising a cover, wherein the sensor units are attached to the cover to be placed on the fingers and the force generating units are attached to the cover to be placed on the fingers.

44. The information input device of claim 41, wherein the cover comprises a glove covering the fingers and a hand to which the fingers are attached.

45. A virtual space keyboard system comprising:
a sensor unit that is attached to a first predetermined part of a finger and which senses motion information of the finger;
an information input processing unit which displays a character based on received location information of the finger with respect to the virtual space keyboard in space;
a processor unit which determines the location information of the finger based on the motion information detected by said sensor unit, sends the location information to said information input processing unit and generates an input completion signal to be output; and
a force generating unit that is attached to a second predetermined part of the finger and, which applies a force to the finger in response to the input completion signal output from said processor unit.

46. The virtual space keyboard system of claim 45 further comprising:
additional sensor units that are attached to other first predetermined parts of other fingers and which sense other motion of the other fingers, wherein
the information input processing unit additionally displays other characters based on received other location information of the other fingers with respect to the virtual space keyboard in space, and
the processor unit additionally determines the other location information of the other fingers based on the other motion information detected by said additional sensor units, sends the other location information to said information input processing unit and generates other input completion signals to be output; and
additional force generating units that are attached to other second predetermined parts of the other fingers, wherein each said additional force generating unit generates another force to a corresponding other second predetermined part of one of the other fingers in response to a received one of the other input completion signals.

47. A virtual space keyboard system to input information to a computer, the virtual space keyboard system comprising:
a sensor unit that is attached to a first predetermined part of a finger and which senses motion information of the finger;
a processor unit which determines location information of the finger with respect to the virtual space keyboard in space based on the motion information detected by said sensor unit, sends the location information to the computer and generates an input completion signal to output; and
a force generating unit that is attached to a second predetermined part of the finger, which applies a force to the finger in response to the input completion signal.

48. The virtual space keyboard system of claim 47, further comprising:
additional sensor units that are attached to other first predetermined parts of other fingers and which sense other motion information of the other fingers, wherein
the processor unit additionally determines other location information of the other fingers with respect to the virtual space keyboard in space based on the other motion information detected by said additional sensor units, sends the other location information to the computer and generates other input completion signals to be output; and
additional force generating units that are attached to other second predetermined parts of the other fingers, wherein each said additional force generating unit generates another force to a corresponding other second predetermined part of a one of the other fingers in response to a received one of the other input completion signals.
